(19) United States
(12) Patent Application Publication
(10) Pub. No.: US 2025/0338572 A1
(43) Pub. Date: Oct. 30, 2025

(54) SEMICONDUCTOR STRUCTURE AND FABRICATION METHODS THEREOF

(71) Applicant: Semiconductor Manufacturing International (Shanghai) Corporation, Shanghai (CN)

(72) Inventors: Jaewoo KIM, Shanghai (CN); Byungsup SHIM, Shanghai (CN); Weinan JIN, Shanghai (CN); Yang DONG, Shanghai (CN)

(21) Appl. No.: 19/193,016

(22) Filed: Apr. 29, 2025

(30) Foreign Application Priority Data
Apr. 29, 2024 (CN) 202410533384.7

(51) Int. Cl. H10D 62/10; H10D 30/00; H10D 30/01; H10D 30/43; H10D 64/01; H10D 84/01; H10D 84/83

(52) U.S. Cl. CPC H10D 62/115; H10D 30/014; H10D 30/0191; H10D 30/43; H10D 30/502; H10D 62/102; H10D 62/121; H10D 64/017; H10D 84/0128; H10D 84/0151; H10D 84/832

(57) ABSTRACT

A semiconductor structure includes a substrate; a plurality of isolation stack layers located on the substrate, an isolation stack layer of the plurality of isolation stack layers including a plurality of isolation layers spaced apart in a vertical direction; and a plurality of channel layer structures each located on one isolation stack layer, a channel layer structure of the plurality of channel layer structures including a plurality of channel layers spaced apart in the vertical direction, sidewalls of adjacent channel layer structures forming a groove penetrating through the plurality of channel layer structures in the vertical direction, and the groove further extending into the plurality of isolation stack layers in the vertical direction.

### CROSS-REFERENCE TO RELATED APPLICATION

This application claims the priority of Chinese Patent Application No. 202410533384.7, filed on Apr. 29, 2024, the entire content of which is incorporated herein by reference.

### FIELD OF THE DISCLOSURE

The present disclosure generally relates to the field of semiconductor fabrication technology and, more particularly, relates to a semiconductor structure and a method for forming the same.

### BACKGROUND

A field effect transistor (FET) with a gate-all-around nanosheet (GAA NA) structure, or GAA-FET, can carry more current and maintain a smaller size. The GAA transistor evolved from a fin field effect transistor. The fin field effect transistor is also called FinFET. Compared with a fin field effect transistor, a GAA transistor reduces the supply voltage and enhances the current driving capability, thereby further improving performance. In particular, a GAA-FET has better electrostatic properties than a FinFET.

The use of GAA transistors in large-scale or even ultra-large-scale integrated circuits may cause serious bottom parasitic channel leakage. To solve this problem, a bottom dielectric isolation (BDI) layer is set under the source, drain, gate and other regions of the GAA transistor.

### SUMMARY OF THE DISCLOSURE

Embodiments of the present disclosure provides a semiconductor structure. The semiconductor structure includes: a substrate; a plurality of isolation stack layers located on the substrate; and a plurality of channel layer structures each located on one isolation stack layer. An isolation stack layer includes a plurality of isolation layers spaced apart along a vertical direction. A channel layer structure includes a plurality of channel layers spaced apart along the vertical direction, sidewalls of adjacent channel layer structures forming a groove that penetrates the channel layer structure along the vertical direction, and the groove extending into the isolation stack layer along the vertical direction.

Optionally, the groove extends in the vertical direction to expose the bottommost isolation layer.

Optionally, the groove does not penetrate the isolation stack layer, so that the bottommost isolation stack layers in adjacent isolation stacks are connected.

Optionally, the semiconductor structure further includes: a gate structure, which is located on the substrate and crosses the channel layer structure, the gate structure surrounds the channel layer, and is filled between vertically adjacent channel layers.

Optionally, the gate structure also spans the isolation stack layer and surrounds the isolation layer. And the gate structure fills between vertically adjacent isolation layers.

Optionally, the material of an isolation layer includes one or more of silicon oxide, silicon nitride, silicon oxynitride, silicon oxycarbide, silicon carbonitride, and silicon carbon oxynitride.

Various embodiments of the present disclosure also provides a method for forming the semiconductor structure. The method includes: providing the substrate; forming the channel layer structure over the substrate; and forming the isolation stack layer between the channel layer structure and the substrate. The channel layer structure includes the plurality of channel layers spaced apart along the vertical direction and the sidewalls of adjacent channel layer structures forming the groove that penetrates the channel layer structure along the vertical direction. The isolation stack layer includes the plurality of isolation layers spaced apart along the vertical direction and the groove extending into the isolation stack layer along the vertical direction.

Optionally, steps of forming the channel layer structure over the substrate, the channel layer structure comprising the plurality of channel layers spaced apart in the vertical direction include: forming a first material stack over the substrate; and patterning the first material stack to form the groove penetrating the first material stack. The first material stack comprising alternately stacked channel material layers and a first sacrificial layer, wherein the bottom layer of the first material stack is the channel material layer, and the etching resistance of the first sacrificial layer is less than the etching resistance of the channel material layer. The groove divides the first material stack into a plurality of discrete first stack structures, and retains the channel material layer in the first stack structure as the channel layer and the plurality of channel layers in the first stack structure constitute the channel layer structure.

Optionally, before forming the first material stack over the substrate, the formation method also includes: forming a second material stack covering the substrate, the second material stack including alternately stacked a second sacrificial layer and a third sacrificial layer, wherein the topmost and bottommost layers of the second material stack are the second sacrificial layer, and the etching resistance of the second sacrificial layer is less than that of the third sacrificial layer; in the step of forming the first material stack over the substrate, the first material stack covering the second material stack; before patterning the first material stack, the formation method also including: forming an isolation layer at the position of the second sacrificial layer; and in the step of patterning the first material stack, it also including: patterning the third sacrificial layer and the isolation layer under the channel layer structure to form a second stack structure located under the first stack structure, wherein the multiple isolation layers in the second stack structure constitute the isolation stack layer, and the groove extends vertically into the isolation stack layer.

Optionally, in the step of forming the second material stack covering the substrate, the third sacrificial layer is made of the same material as the first sacrificial layer.

Optionally, in the step of patterning the third sacrificial layer and the isolation stack layer under the channel layer structure to form a second stacked structure located under the first stacked structure, the groove extends vertically to the bottommost isolation stack layer and exposes the isolation stack layer.

Optionally, in the step of patterning the third sacrificial layer and the isolation stack layer under the channel layer structure to form the second stacked structure located under the first stacked structure, the bottommost isolation stack layers in adjacent isolation stack layers are connected.

Optionally, the step of forming the isolation stack layer at the position of the second sacrificial layer includes: removing the second sacrificial layer to form a first groove exposing the bottom of the first material stack, a top surface of the substrate, and the third sacrificial layer in the second material stack; and forming the isolation layer filling the first groove.

Optionally, before forming the isolation layer at the position of the second sacrificial layer, the forming method further includes: forming a pseudo gate structure spanning the first material stack and the second material stack, the pseudo gate structure covering part of the top and part of the sidewall of the first material stack, and covering part of the sidewall of the second material layer; in the step of patterning the first material stack, the first material stack patterned along the pseudo gate structure, and the first material stack on both sides of the pseudo gate structure removed; and after forming an isolation stack between the channel layer structure and the substrate, the forming method further including: removing the pseudo gate structure to expose the first stack structure and the second stack structure.

Optionally, after removing the pseudo gate structure, the forming method further includes: removing the first sacrificial layer in the first stack structure to form a second groove exposing the channel layer; and forming the gate structure spanning the channel layer structure and filling the second groove, the gate structure surrounding the channel layer.

Optionally, the step of removing the first sacrificial layer in the first stacked structure further includes: removing the third sacrificial layer in the second stacked structure to form a third groove exposing the isolation layer; and in the step of forming a gate structure that spans the channel layer structure and fills the second groove, the gate structure also spanning the isolation stack and fills the third groove.

Optionally, an epitaxial growth process is used to form a first material stack over the substrate.

Optionally, in the step of forming the first material stack over the substrate, the material of the first sacrificial layer includes silicon germanium and the material of the channel material layer includes silicon.

Optionally, an epitaxial growth process is used to form the second material stack covering the substrate.

Optionally, in the step of forming the second material stack covering the substrate, the material of the second sacrificial layer includes silicon germanium, and the material of the third sacrificial layer includes silicon germanium, wherein a molar concentration of a germanium element in the second sacrificial layer is greater than a molar concentration of a germanium element in the third sacrificial layer.

Compared with current techniques, the technical scheme of the embodiment of the present disclosure has several advantages:

In the semiconductor structure provided by the embodiment of the present disclosure, the isolation stack layer is located on the substrate. The isolation stack layer includes the plurality of isolation layers spaced apart in the vertical direction, the channel layer structure located on the isolation stack layer, the channel layer structure included the plurality of channel layers spaced apart in the vertical direction, the sidewalls of adjacent channel layer structures formed the groove penetrating the channel layer structure in the vertical direction, and the groove extended into the isolation stack layer in the vertical direction. In the embodiment of the present disclosure, the groove formed by the sidewalls of adjacent channel layer structures extends into the isolation stack layer in the vertical direction, and the isolation stack layer is a stacked structure with multiple isolation layers spaced apart, so the depth adjustment window of the groove extending into the isolation stack layer is relatively large. The groove can be extended to a greater depth in the isolation stack layer, so that the sidewall of the channel layer structure is located in the groove at a position relatively far from the bottom of the groove, which is beneficial to reduce the probability of defects in sidewalls of the channel layer structure due to the process, which is easy to have slopes near the bottom of the groove, and is beneficial to improve the verticality of sidewalls of the channel layer structure, which is beneficial to improve the consistency of channel lengths of multiple channel layers, thereby reducing the probability of unstable performance or noise generation of the semiconductor structure, and at the same time, it is beneficial to ensure sufficient space between bottom channel layers in adjacent channel layer structures. It is used to form a source-drain doping layer of sufficient size, which is beneficial to ensure the mobility of the semiconductor structure, and further beneficial to ensure the performance of the semiconductor structure.

In the fabrication method provided in the embodiment of the present disclosure, a channel layer structure over the substrate is formed. The channel layer structure includes the plurality of channel layers spaced apart in the vertical direction, the sidewalls of adjacent channel layer structures formed the groove penetrating the channel layer structure in the vertical direction, the isolation stack layer formed between the channel layer structure and the substrate, the isolation stack layer included the plurality of isolation stacks spaced apart in the vertical direction, and the groove extended into the isolation stack layer in the vertical direction. In the embodiment of the present disclosure, the groove formed by the sidewalls of adjacent channel layer structures extends into the isolation stack layer in the vertical direction, and the isolation stack layer is a stacked structure having the plurality of isolation layers spaced apart, and the depth adjustment window of the groove extending into the isolation stack is larger, and the groove can be extended to a greater depth in the isolation stack layer, so that the sidewall of the channel layer structure is located in the groove at a position far away from the bottom of the groove, which is conducive to reducing the probability of defects in the sidewall near the bottom of the groove due to process influence, and is conducive to improving the verticality of the sidewall of the channel layer structure, which is conducive to improving the consistency of the channel length of multiple channel layers, thereby reducing the probability of unstable performance or noise generation of the semiconductor structure, and at the same time, it is conducive to ensuring sufficient space between bottom channel layers in adjacent channel layer structures. It is used to form the source-drain doping layer of sufficient size, which is conducive to ensuring the mobility of the semiconductor structure, and further conducive to ensuring the performance of the semiconductor structure.

### BRIEF DESCRIPTION OF THE DRAWINGS

The following drawings are merely examples for illustrative purposes according to various disclosed embodiments and are not intended to limit the scope of the present disclosure.

FIG. 1 is a schematic structural diagram corresponding to a semiconductor structure;

FIGS. 2-3 are schematic structural diagrams of an exemplary semiconductor structure in accordance with various embodiments of the present disclosure; and

FIGS. 4-12 are schematic diagrams of structures at certain stages during a fabrication process of an exemplary semiconductor structure in accordance with various embodiments of the present disclosure.

### DETAILED DESCRIPTION

Reference will now be made in detail to exemplary embodiments of the disclosure, which are illustrated in the accompanying drawings. Wherever possible, the same reference numbers will be used throughout the drawings to refer to the same or like parts.

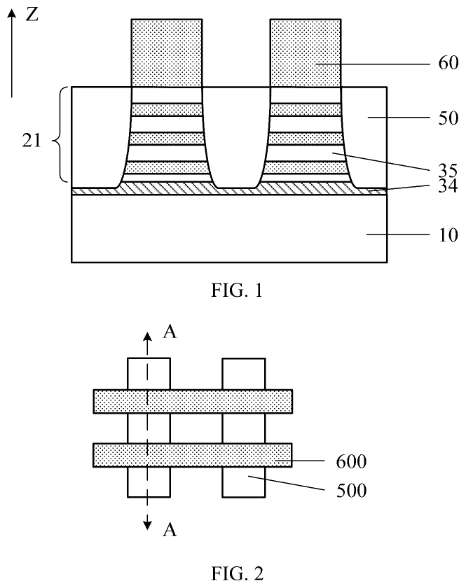

FIG. 1 is a schematic structural diagram corresponding to the semiconductor structure.

Referring to FIG. 1, the semiconductor structure includes: a substrate 10; an isolation layer 34, located on the substrate 10; a channel layer structure 21, located on the isolation layer 34a gate structure 60, spanning the channel layer structure 21 and surrounding each channel layer 35; and a source-drain doping layer 50, located on the substrate 10 on both sides of the gate structure 60. The channel layer structure 21 includes a plurality of channel layers 35 spaced apart in the vertical direction (as shown in the Z direction in FIG. 1). The source-drain doping layer 50 is in contact with the end of the channel layer structure 21.

Since the isolation layer 34 is relatively thin, when etching forms the channel layer structure 21, the distance between the sidewall of the channel layer structure 21 and the bottom of the etching is very close. Due to the influence of the etching process, the sidewall verticality of the channel layer structure 21 is likely to be poor, especially the sidewall slope under the channel layer structure 21 close to the isolation layer 34 is relatively large, which is likely to cause channel lengths of multiple channel layers 35 to be inconsistent, thereby causing the performance of the semiconductor structure to be unstable or generate noise. It is also likely to cause insufficient space between bottom channel layers 35 in adjacent channel layer structures 21, resulting in insufficient size of a source-drain doping layer 50 formed between adjacent channel layer structures 21, thereby affecting the mobility of the semiconductor structure, and further affecting the performance of the semiconductor structure.

In order to solve the technical problem, the embodiment of the present disclosure provides the semiconductor structure, including: a substrate; an isolation stack layer located on the substrate; and a channel layer structure located on the isolation stack layer. The isolation stack layer includes a plurality of isolation layers spaced apart in a vertical direction. The channel layer structure includes a plurality of channel layers spaced apart in the vertical direction. Sidewalls of adjacent channel layer structures enclose a groove that penetrates the channel layer structure in the vertical direction, and the groove extends into the isolation stack layer in the vertical direction.

In the embodiment of the present disclosure, the grooves formed by the sidewalls of adjacent channel layer structures extend vertically into the isolation stack layer, and the isolation stack layer is a stacked structure with multiple isolation layers spaced apart. The depth adjustment window of the groove extending into the isolation stack layer is large, and sidewalls of the channel layer structure can be located in the groove at a position relatively far from the bottom of the groove by making the groove extend to a greater depth into the isolation stack layer, which is beneficial to reducing the probability of sidewalls near the bottom of the groove having a slope due to process influence appearing on the sidewalls of the channel layer structure, and is beneficial to improving the verticality of the sidewalls of the channel layer structure, and is correspondingly beneficial to improving the consistency of channel lengths of multiple channel layers, thereby reducing the probability of unstable performance or noise generation of the semiconductor structure, and at the same time, is correspondingly beneficial to ensuring sufficient space between the bottommost channel layers of adjacent channel layer structures. It is used to form a source-drain doping layer of sufficient size, thereby facilitating the mobility of the semiconductor structure, and further facilitating the performance of the semiconductor structure.

In order to make the above-mentioned purposes, features and advantages of the present disclosure more obvious and easy to understand, the specific embodiments of the present disclosure are described in detail below in conjunction with the accompanying drawings.

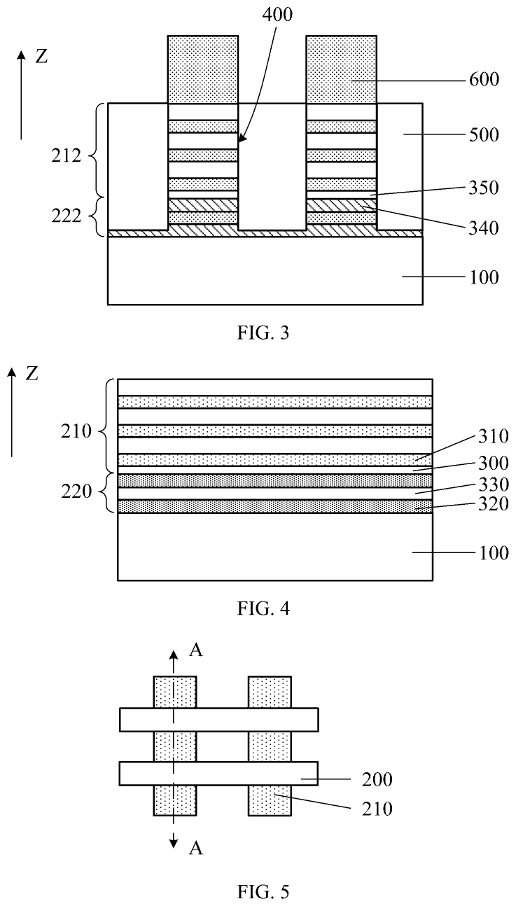

FIGS. 2-3 are schematic diagrams of structures corresponding to an embodiment of a semiconductor structure of the present disclosure.

Referring to FIGS. 2-3, FIG. 3 is a cross-sectional view of FIG. 2 along the AA direction. The semiconductor structure includes: a substrate 100; isolation stack layers 222, located on the substrate 100; and channel layer structures 212, located on the isolation stack layers 222. An isolation stack layer 222 includes a plurality of isolation layers 340 spaced apart in the vertical direction (as shown in the Z direction in FIG. 3). A channel layer structure 212 includes a plurality of channel layers 350 spaced apart in the vertical direction. The sidewalls of adjacent channel layer structures 212 form a groove 400 that penetrates the channel layer structures 212 in the vertical direction, and the groove 400 extends into the isolation stack layer 222 in the vertical direction.

The substrate 100 provides a process operation basis for the formation process of the semiconductor structure.

In one embodiment, the material of the substrate 100 is silicon. In other embodiments, the material of the substrate can also be other materials such as germanium, silicon germanium, silicon carbide, gallium arsenide or indium gallium, and the substrate can also be other types of substrates such as silicon substrate on an insulator or a germanium substrate on insulator. The material of the substrate can be a material suitable for process requirements or easy to integrate.

The channel layer structure 212 includes the plurality of channel layers 350 spaced apart in the vertical direction, and the channel layer 350 is used as a channel of the transistor.

In one embodiment, the material of the channel layer 350 includes silicon, germanium, silicon germanium or III-V semiconductor material. As an example, the material of the channel layer 350 is silicon. In other embodiments, the material of the channel layer is determined according to the type and performance of the transistor.

The isolation stack layer 222 is used to isolate the channel layer structure 212 from the substrate 100, and a gate structure surrounding the channel layer 350 from the substrate 100, effectively isolating a contact between the channel layer 350 and the substrate 100, and the contact between the gate structure and the substrate 100, thereby reducing the probability of leakage current between the gate structure and the substrate 100, and at the same time, when the channel layer 350 is turned on, it reduces or avoids a situation where the parasitic capacitance of the substrate 100 increases due to being turned on.

In the present embodiment, the groove 400 formed by the sidewalls of adjacent channel layer structures 212 extends vertically into the isolation stack layer 222, and the isolation stack layer 222 is a stack structure having multiple isolation layers 340 spaced apart from each other. Thus, the depth adjustment window of the groove 400 extending into the isolation stack layer 222 is relatively large. By making the depth of the groove 400 extending into the isolation stack layer 222 relatively large, the sidewall of the channel layer structure 212 is located in the groove 400 relatively far away from the bottom of the groove 400. This helps to reduce the probability of the sidewall of the channel layer structure 212 having a slope due to process influences, and helps to improve the verticality of the sidewall of the channel layer structure 212. This helps to improve the consistency of channel lengths of the multiple channel layers 350, thereby helping to reduce the probability of unstable performance or noise generation of the semiconductor structure. At the same time, this helps to ensure sufficient space between bottom channel layers 350 in adjacent channel layer structures 212. Used to form a source-drain doping layer of sufficient size, which is beneficial to guarantee the mobility of the semiconductor structure, and further beneficial to guarantee the performance of the semiconductor structure.

In one embodiment, the groove 400 extends vertically to expose the bottom isolation layer 340.

The groove 400 extends vertically to expose the bottom isolation layer 340, so that the groove 400 extends to a greater depth in the isolation stack layer 222, which is beneficial to further make the sidewall of the channel layer structure 212 away from the bottom of the groove 400, which is beneficial to further improve the verticality of the sidewall of the channel layer structure 212, and correspondingly helps to further improve the consistency of the channel length of multiple channel layers 350, so as to further reduce the probability of unstable performance or noise generation of the semiconductor structure, and at the same time, it is beneficial to further guarantee sufficient space between bottom channel layers 350 in adjacent channel layer structures 212. Used to form the source-drain doping layer of sufficient size, which is beneficial to further guarantee the mobility of the semiconductor structure.

In one embodiment, the groove 400 does not penetrate the isolation stack layer 222, so that the bottom isolation layer 340 in the adjacent isolation stack layer 222 is connected.

The groove 400 penetrates the isolation stack layer 222, and the bottom isolation layer 340 in an adjacent isolation stack layer 222 is kept connected, so that while the groove 400 extends to a greater depth in the isolation stack layer 222, the bottom isolation layer 340 in the adjacent isolation stack layer 222 is connected, and the isolation layer 340 is retained on the substrate 100 between the adjacent channel layer structures 212, so that the source-drain doping layer formed on the substrate 100 between the adjacent channel layer structures 212 is isolated from the substrate 100, which is conducive to reducing a leakage probability between the source-drain doping layer and the substrate 100.

The groove 400 penetrates the isolation stack layer 222, and the bottom isolation layer 340 in the adjacent isolation stack layer 222 is kept connected, so that while the groove 400 extends to a greater depth in the isolation stack layer 222, the bottom isolation layer 340 in the adjacent isolation stack layer 222 is connected, and the isolation layer 340 is retained on the substrate 100 between the adjacent channel layer structures 212, so that the source-drain doping layer formed on the substrate 100 between the adjacent channel layer structures 212 is isolated from the substrate 100, which is conducive to reducing the leakage probability between the source-drain doping layer and the substrate 100.

In one embodiment, the material of the isolation layer 340 is an insulating material, including one or more of silicon oxide, silicon nitride, silicon oxynitride, silicon oxycarbide, silicon carbonitride, and silicon oxynitride. The isolation layer 340 formed by one or more of silicon oxide, silicon nitride, silicon oxynitride, silicon oxycarbide, silicon carbonitride, and silicon oxynitride has good isolation performance.

In one embodiment, the semiconductor structure also includes: a gate structure 600, which is located on the substrate 100 and crosses the channel layer structure 212. The gate structure 600 surrounds the channel layer 350 and fills between vertically adjacent channel layers 350.

The gate structure 600 is used to control an opening and a closing of the channel of the transistor.

The gate structure 600 surrounds and covers the channel layer 350, so the top, bottom and sidewall of the channel layer 350 can all be used as channels, increasing an area of the channel layer 350 used as a channel, thereby increasing a working current of the semiconductor structure.

Specifically, in the present embodiment, the gate structure 600 includes a gate dielectric layer surrounding the channel layer 350 along the extension direction of the gate structure 600, and a gate electrode layer located on the gate dielectric layer.

The gate dielectric layer is used to isolate the gate electrode layer from the channel layer 350, and the gate electrode layer from the substrate 100.

The material of the gate dielectric layer includes one or more of HfO₂, ZrO₂, HfSiO, HfSiON, HfTaO, HfTiO, HfZrO, Al₂O₃, SiO₂, and La₂O₃. In the present embodiment, the gate dielectric layer includes a high-k gate dielectric layer, and the material of the high-k gate dielectric layer includes a high-k dielectric material. Among them, the high-k dielectric material refers to a dielectric material having a relative dielectric constant greater than the relative dielectric constant of silicon oxide. Specifically, the material of the high-k gate dielectric layer includes HfO₂, ZrO₂, HfSiO, HfSiON, HfTaO, HfTiO, HfZrO, or Al₂O₃, etc.

It should be noted that the gate dielectric layer may also include a gate oxide layer, and the gate oxide layer is located between the high-k gate dielectric layer and the channel layer 350. Specifically, the material of the gate oxide layer may be silicon oxide.

In one embodiment, the gate structure 600 is a metal gate structure, and therefore, the material of the gate electrode layer includes one or more of TiN, TaN, Ta, Ti, TiAl, W, Al, TiSiN, and TiAlC.

Specifically, the gate electrode layer includes a work function layer (not shown), and an electrode layer (not shown) located on the work function layer. Among them, the work function layer is used to adjust a threshold voltage of the transistor, and the electrode layer is used to lead out the electrical properties of the metal gate structure.

In some other embodiments, the gate electrode layer may also include only the work function layer.

In one embodiment, the gate structure 600 also spans the isolation stack layer 340, surrounds the isolation layer 340, and fills between vertically adjacent isolation layers 340.

Surrounding the isolation layer 340. The gate structure 600 filled between the vertically adjacent isolation layers 340 does not play a working role. The gate structure 600 filled between the vertically adjacent isolation layers 340 makes multiple isolation layers 340 spaced apart vertically to form the isolation stack layer 222.

In one embodiment, the semiconductor structure further includes: on the substrate 100 located on both sides of the gate structure 600, in the extension direction of the channel layer structure 212, a source-drain doped layer 500 contacts the end of the channel layer structure 212.

The source-drain doped layer 500 is used as a source region or drain region of the transistor. Specifically, a doping type of the source-drain doped layer 500 is the same as the channel conductivity type of the corresponding transistor.

In one embodiment, the verticality of the sidewall of the channel layer structure 212 is good, and accordingly, there is enough space between the bottommost channel layers 350 in adjacent channel layer structures 212 to form the source-drain doped layer 500 of sufficient size, which is beneficial to ensure the mobility of the semiconductor structure, and further to ensure the performance of the semiconductor structure.

FIGS. 4-12 are schematic diagrams of structures corresponding to each step in an embodiment of the method for forming the semiconductor structure of the present disclosure.

Referring to FIG. 4, the substrate 100 is provided.

The substrate 100 provides the process operation basis for the formation process of the semiconductor structure.

In one embodiment, the material of the substrate 100 is silicon. In other embodiments, the material of the substrate can also be other materials such as germanium, silicon germanium, silicon carbide, gallium arsenide or indium gallium, and the substrate can also be other types of substrates such as a silicon substrate on the insulator or the germanium substrate on an insulator. The material of the substrate can be the material suitable for process requirements or easy to integrate.

Combined with reference to FIGS. 4-9, the channel layer structure 212 over the substrate 100 is formed, and the channel layer structure 212 includes the plurality of channel layers 350 spaced apart in the vertical direction (as shown in the Z direction in FIG. 9), and the sidewalls of adjacent channel layer structures 212 form the groove 400 that penetrates the channel layer structure 212 in the vertical direction.

The channel layer structure 212 includes the plurality of channel layers 350 spaced apart in the vertical direction, and the channel layer 350 is used as a channel of a transistor.

In one embodiment, the material of the channel layer 350 includes silicon, germanium, silicon germanium or III-V semiconductor material. As an example, the material of the channel layer 350 is silicon. In other embodiments, the material of the channel layer is determined according to the type and performance of the transistor.

Referring to FIG. 4, the step of forming the channel layer structure 212 over the substrate 100, wherein the channel layer structure 212 includes the plurality of channel layers 350 spaced apart in the vertical direction, includes: forming a first material stack 210 over the substrate 100, wherein the first material stack 210 includes alternately stacked channel material layers 300 and first sacrificial layers 310, wherein the bottom layer of the first material stack 210 is the channel material layer 300, and the etching resistance of the first sacrificial layer 310 is less than the etching resistance of the channel material layer 300.

The first material stack 210 is used to form the first stack structure, and the channel layer structure 212 is formed accordingly. The channel material layer 300 is used to form the channel layer 350. The first sacrificial layer 310 is used to occupy a space position for the subsequent formation of a gate structure. The etching resistance of the first sacrificial layer 310 is less than that of the channel material layer 300. If the first sacrificial layer 310 needs to be removed while retaining the channel material layer 300, the etching resistance of the first sacrificial layer 310 is less than that of the channel material layer 300, which is conducive to making the first sacrificial layer 310 easy to remove later and reducing a damage to the channel layer 350 when removing the first sacrificial layer 310.

In one embodiment, in the step of forming the first material stack 210 over the substrate 100, the material of the first sacrificial layer 310 includes silicon germanium, and the material of the channel material layer 300 includes silicon.

The material of the first sacrificial layer 310 includes silicon germanium, and the material of the channel material layer 300 includes silicon, which can make the etching resistance of the first sacrificial layer 310 less than the etching resistance of the channel material layer 300.

In one embodiment, the first material stack 210 over the substrate 100 is formed by an epitaxial growth process.

The epitaxial growth process can better control process parameters, has high process controllability, and is easy to obtain a more accurate film thickness size. The epitaxial growth process is easy to form a film with fewer impurities, so that the quality of the channel material layer 300 is higher. Moreover, the material of the first sacrificial layer 310 is silicon germanium, and the material of the channel material layer 300 is silicon. The epitaxial growth process can grow the first sacrificial layer 310 on the channel material layer 300, and grow the channel material layer 300 on the first sacrificial layer 310, so that the first material stack 210 is formed in the same process.

Continue to refer to FIG. 4, before forming the first material stack 210 over the substrate 100, the formation method also includes: forming a second material stack 220 covering the substrate 100, the second material stack 220 includes a second sacrificial layer 320 and a third sacrificial layer 330 stacked alternately, wherein top and bottom layers of the second material stack 220 are the second sacrificial layer 320, and the etching resistance of the second sacrificial layer 320 is less than the etching resistance of the third sacrificial layer 330.

The second material stack 220 is used to form a second stack structure, and then form the isolation stack layer accordingly. The second sacrificial layer 320 is used to occupy a space position for the subsequent formation of the isolation layer, and the third sacrificial layer 330 is used to occupy a space position for the subsequent formation of a gate structure. Among them, top and bottom layers of the second material stack 220 are the second sacrificial layer 320, and top and bottom layers of the second stack structure formed subsequently are isolation layers, so that the top isolation layer can isolate the channel layer structure 212, and the bottom isolation layer can isolate the gate structure. The second sacrificial layer 320 needs to be removed and the third sacrificial layer 330 needs to be retained. The etching resistance of the second sacrificial layer 320 is less than that of the third sacrificial layer 330, which is conducive to making the second sacrificial layer 320 easy to remove later, and also conducive to reducing the damage to the third sacrificial layer 330 when removing the second sacrificial layer 320.

In one embodiment, in the step of forming the second material stack 220 covering the substrate 100, the material of the second sacrificial layer 320 includes silicon germanium, and the material of the third sacrificial layer 330 includes silicon germanium, wherein the molar concentration of the germanium element in the second sacrificial layer 320 is greater than the molar concentration of the germanium element in the third sacrificial layer 330.

The material of the second sacrificial layer 320 includes silicon germanium, and the material of the third sacrificial layer 330 includes silicon germanium. The molar concentration of germanium in the second sacrificial layer 320 is greater than the molar concentration of germanium in the third sacrificial layer 330, which can make the etching resistance of the second sacrificial layer 320 less than the etching resistance of the third sacrificial layer 330.

In one embodiment, an epitaxial growth process is used to form the second material stack 220 over the substrate 100.

The epitaxial growth process can better control process parameters, has high process controllability, and is easy to obtain a more accurate film thickness size. The epitaxial growth process is easy to form a film with fewer impurities, so that the second sacrificial layer 320 and the third sacrificial layer 330 have higher quality. Moreover, the material of the second sacrificial layer 320 is silicon germanium, and the material of the third sacrificial layer 330 is silicon. The epitaxial growth process can grow the third sacrificial layer 330 on the second sacrificial layer 320, and grow the second sacrificial layer 320 on the third sacrificial layer 330, so that the second material stack 220 is formed in the same process.

In one embodiment, in the step of forming the first material stack 210 over the substrate 100, the first material stack 210 covers the second material stack 220.

Accordingly, in one embodiment, an epitaxial growth process is used to form a second material stack 220 and a first material stack 210 covering the second material stack 220 in the same process.

In one embodiment, in the step of forming the second material stack 220 covering the substrate 100, the third sacrificial layer 330 is made of the same material as the first sacrificial layer 310.

The third sacrificial layer 330 is made of the same material as the first sacrificial layer 310, which can achieve that the etching resistance of the first sacrificial layer 310 is less than that of the channel material layer 300, and the etching resistance of the second sacrificial layer 320 is less than that of the third sacrificial layer 330, while reducing the introduction of too many different elements. Moreover, the third sacrificial layer 330 and the first sacrificial layer 310 can be removed simultaneously in the subsequent process to form a gate structure, simplifying the process flow and improving the process efficiency.

It should be noted that, in one embodiment, the topmost layer of the second material stack 220 is the second sacrificial layer 320, and the bottommost layer of the first material stack 210 is the channel material layer 300. The etching resistance of the first sacrificial layer 310 is less than that of the channel material layer 300, and the etching resistance of the second sacrificial layer 320 is less than that of the third sacrificial layer 330. The third sacrificial layer 330 is made of the same material as the first sacrificial layer 310, which is beneficial to a subsequent removal of the second sacrificial layer 320. A damage to the channel material layer 300 is small, which is beneficial to ensure the film quality of the channel layer structure 212.

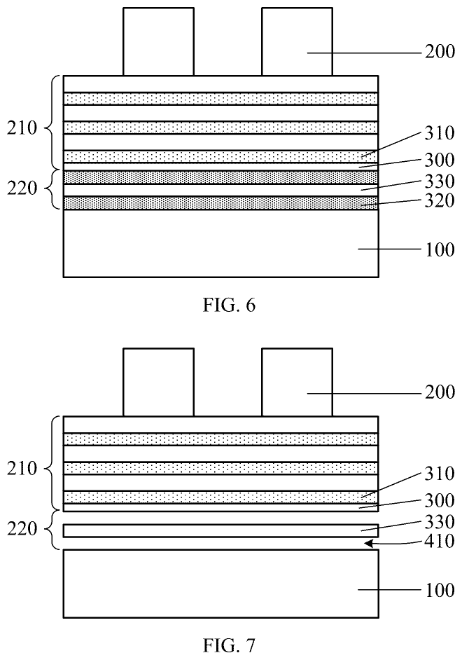

In conjunction with reference to FIGS. 5-6, FIG. 6 is a cross-sectional view of FIG. 5 along the AA direction. Before subsequently forming an isolation layer at the position of the second sacrificial layer 320, the formation method further includes: forming a pseudo gate structure 200 spanning the first material stack 210 and the second material stack 220, the pseudo gate structure 200 covering a portion of the top and a portion of the sidewall of the first material stack 210, and covering a portion of the sidewall of the second material layer 220.

The pseudo gate structure 200 is used to occupy a spatial position for the subsequent formation of a gate structure.

In one embodiment, the material of the pseudo gate structure 200 includes silicon.

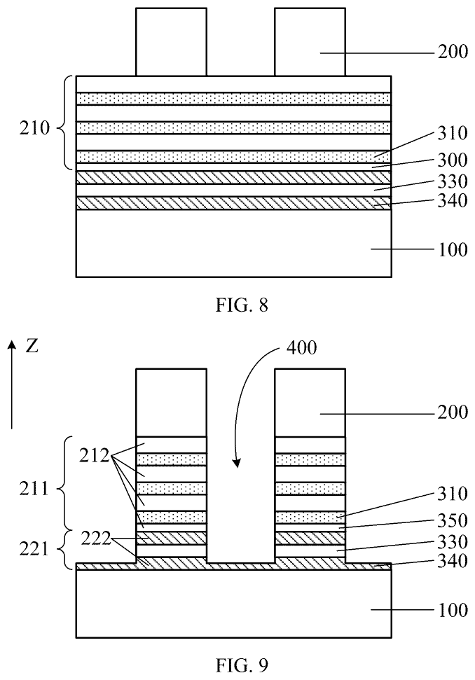

In conjunction with reference to FIGS. 7-8, before subsequently patterning the first material stack 210, the formation method further includes: forming an isolation layer 340 at the position of the second sacrificial layer 320.

The isolation layer 340 is used to isolate the channel layer structure 212 from the substrate 100, and the gate structure surrounding the channel layer 350 and the substrate 100 formed subsequently.

In one embodiment, in the step of forming the isolation layer 340 at the position of the second sacrificial layer 320, the material of the isolation layer 340 is the insulating material, including one or more of silicon oxide, silicon nitride, silicon oxynitride, silicon oxycarbide, silicon carbonitride and carbon oxynitride silicon.

The isolation layer 340 formed by one or more of silicon oxide, silicon nitride, silicon oxynitride, silicon oxycarbide, silicon carbonitride and carbon oxynitride silicon has good isolation performance.

Referring to FIG. 7, the step of forming the isolation layer 340 at the position of the second sacrificial layer 320 includes: removing the second sacrificial layer 320, forming a first groove 410 exposing the bottom of the first material stack 210, a top surface of the substrate 100, and the third sacrificial layer 330 in the second material stack 220.

The first groove 410 is used to provide a spatial position for forming the isolation layer 340.

In one embodiment, a wet etching process is used to remove the second sacrificial layer 320.

A cost of the wet etching process is relatively low, operation steps are simple, and a large etching selectivity ratio can be achieved, which is beneficial to reduce the damage to the third sacrificial layer 330 and the first material stack 210 during the removal of the second sacrificial layer 320.

Referring to FIG. 8, the isolation layer 340 is formed to fill the first groove 410.

The isolation layer 340 is formed to fill the first groove 410, and the plurality of isolation layers 340 spaced apart in the vertical direction are obtained.

In one embodiment, an atomic layer deposition process is used to form an isolation layer 340 to fill the first groove 410.

The thickness uniformity of the isolation layer 340 formed by the atomic layer deposition process is good, and the atomic layer deposition process has good step coverage capability, so that the isolation layer 340 can well conformally fill the first groove 410.

Referring to FIG. 9, the first material stack 210 is patterned to form the groove 400 that penetrates the first material stack 210. The groove 400 divides the first material stack 210 into a plurality of discrete first stack structures 211, and retains the channel material layer 300 in the first stack structure 211 as the channel layer 350. The plurality of channel layers 350 in the first stack structure 211 constitutes the channel layer structure 212.

The groove 400 is used to provide a spatial position for the subsequent formation of the source and drain doping layer.

Specifically, in the present embodiment, in the step of patterning the first material stack 211, the first material stack 211 is patterned along the pseudo gate structure 200, and the first material stack 211 on both sides of the pseudo gate structure 200 is removed.

Continuing to refer to FIG. 9, the isolation stack layer 222 is formed between the channel layer structure 212 and the substrate 100. The isolation stack layer 222 includes the plurality of isolation layers 350 spaced apart in the vertical direction, and the groove 400 extends into the isolation stack layer 222 in the vertical direction.

The isolation stack 222 is used to isolate the channel layer structure 212 from the substrate 100, and the gate structure surrounding the channel layer 350 from the substrate 100, effectively isolating the contact between the channel layer 350 and the substrate 100, and the contact between the gate structure and the substrate 100, thereby reducing the probability of leakage current between the gate structure and the substrate 100, and at the same time, when the channel layer 350 is turned on, the situation where the parasitic capacitance of the substrate 100 increases due to being turned on is reduced or avoided.

In one embodiment, the groove 400 formed by sidewalls of adjacent channel layer structures 212 extends vertically into the isolation stack layer 222, and the isolation stack layer 222 is a stacked structure with multiple isolation layers 340 spaced apart. The depth adjustment window of the groove 400 extending into the isolation stack layer 222 is large, and the sidewall of the channel layer structure 212 can be located in the groove 400 at a position far away from the bottom of the groove 400 by making the groove 400 extend to a greater depth into the isolation stack layer 222. This is beneficial to reducing the probability of the sidewall of the channel layer structure 212 having a slope due to the process, and is beneficial to improving the verticality of the sidewall of the channel layer structure 212. It is beneficial to improve the consistency of the channel length of multiple channel layers 350, thereby reducing the probability of unstable performance or noise generation of the semiconductor structure. At the same time, it is beneficial to ensure sufficient space between bottom channel layers 350 in the adjacent channel layer structures 212. It is used to form the source-drain doping layer of sufficient size, which is beneficial to ensure the mobility of the semiconductor structure, and further beneficial to ensure the performance of the semiconductor structure.

In one embodiment, the step of patterning the first material stack 211 also includes: patterning the third sacrificial layer 330 and the isolation layer 340 under the channel layer structure 212 to form a second stack structure 221 located under the first stack structure 211, and the multiple isolation layers 340 in the second stack structure 221 constitute the isolation stack layer 222, and the groove 400 extends vertically into the isolation stack layer 222.

In one embodiment, in the step of patterning the third sacrificial layer 330 and the isolation layer 340 under the channel layer structure 212 to form the second stack structure 221 located under the first stack structure 211, the groove 400 extends vertically into the isolation layer 340 at the bottom, and the isolation layer 340 is exposed.

The groove 400 extends vertically to expose the bottom isolation layer 340, so that the groove 400 extends to a greater depth in the isolation stack layer 222, which is conducive to further making the sidewall of the channel layer structure 212 away from the bottom of the groove 400, and is conducive to further improving the verticality of the sidewall of the channel layer structure 212, and correspondingly is conducive to further improving the consistency of the channel length of multiple channel layers 350, thereby further reducing the probability of unstable performance or noise generation of the semiconductor structure, and at the same time, correspondingly is conducive to further ensuring sufficient space between bottom channel layers 350 in adjacent channel layer structures 212. It is used to form the source-drain doping layer of sufficient size, thereby further ensuring the mobility of the semiconductor structure.

In one embodiment, in the step of patterning the third sacrificial layer 330 and the isolation layer 340 under the channel layer structure 212 to form the second stacked structure 221 located under the first stacked structure 211, the bottom isolation layers 340 of adjacent isolation stack layers 222 are connected.

The groove 400 penetrates the isolation stack layer 222, and the bottom isolation layers 340 of adjacent isolation stack layers 222 are kept connected, so that while ensuring that the groove 400 extends to a greater depth in the isolation stack layer 222, the bottom isolation layers 340 of adjacent isolation stack layers 222 are connected, and the isolation layer 340 is retained on the substrate 100 between adjacent channel layer structures 212, so that the source-drain doping layer formed on the substrate 100 between the adjacent channel layer structures 212 is isolated from the substrate 100, which is conducive to reducing the leakage probability between the source-drain doping layer and the substrate 100.

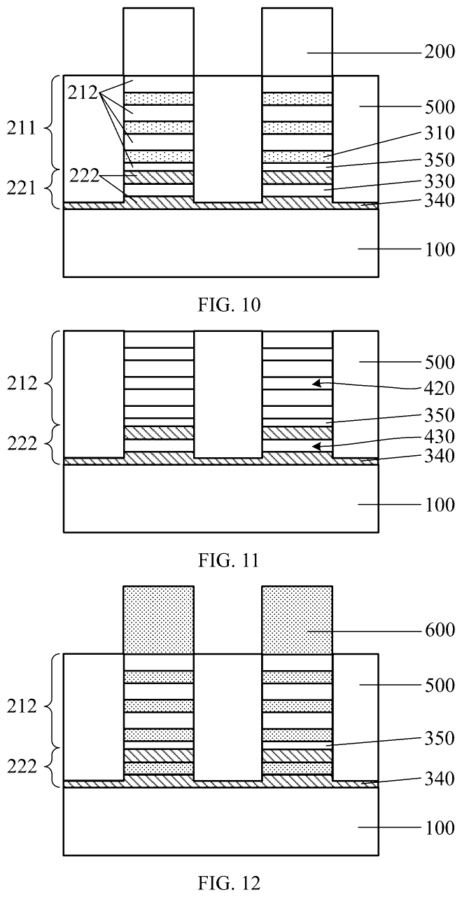

Referring to FIG. 10, the source-drain doping layer 500 is formed in the groove 400, and the source-drain doping layer 500 contacts the end of the channel layer structure 212.

The source-drain doping layer 500 is used as the source region or a drain region of a transistor. Specifically, the doping type of the source-drain doping layer 500 is the same as the channel conductivity type of the corresponding transistor.

In one embodiment, the verticality of the sidewall of the channel layer structure 212 is good, and accordingly, there is enough space between bottom channel layers 350 in adjacent channel layer structures 212 to form the source-drain doping layer 500 of sufficient size, which is beneficial to ensure the mobility of the semiconductor structure, and further to ensure the performance of the semiconductor structure.

Referring to FIG. 11, after forming the isolation stack layer 222 between the channel layer structure 212 and the substrate 100, the formation method further includes: removing the pseudo gate structure 200 to expose the first stack structure 211 and the second stack structure 221.

Removing the pseudo gate structure 200 to expose the first stack structure 211 and the second stack structure 221, prepares for removing the first sacrificial layer 310 and the third sacrificial layer 330.

Continuing to refer to FIG. 11, after removing the dummy gate structure 200, the formation method further includes: removing the first sacrificial layer 310 in the first stack structure 211 to form a second groove 420 exposing the channel layer 350.

The second groove 420 is used to provide a spatial position for the subsequent formation of a gate structure.

In one embodiment, a wet etching process is used to remove the first sacrificial layer 310.

The cost of the wet etching process is relatively low, and operation steps are simple. It can also achieve a large etching selectivity ratio, which is beneficial to reduce the damage to the channel layer 350 during the removal of the first sacrificial layer 310.

In one embodiment, the step of removing the first sacrificial layer 310 in the first stacked structure 211 also includes: removing the third sacrificial layer 330 in the second stacked structure 221 to form a third groove 430 exposing the isolation layer 340.

The third groove 430 is used to provide a spatial position for the subsequent formation of a gate structure.

In one embodiment, a wet etching process is used to remove the third sacrificial layer 330.

The cost of the wet etching process is relatively low, operation steps are simple, and a large etching selectivity ratio can be achieved, which is beneficial to reduce the damage to the channel layer 350 in the process of removing the third sacrificial layer 330.

In one embodiment, the first sacrificial layer 310 and the third sacrificial layer 330 are made of the same material, so the first sacrificial layer 310 and the third sacrificial layer 330 can be removed in the same step, which simplifies the process steps and improves the process efficiency.

Referring to FIG. 12, the gate structure 600 is formed that crosses the channel layer structure 212 and fills the second groove 420, and the gate structure 600 surrounds the channel layer 350.

The gate structure 600 is used to control the opening and the closing of the channel of the transistor.

The gate structure 600 surrounds and covers the channel layer 350. Therefore, the top, bottom and sidewall of the channel layer 350 can all be used as channels, which increases the area of the channel layer 350 used as a channel, thereby increasing the working current of the semiconductor structure.

Specifically, in one embodiment, the gate structure 600 includes the gate dielectric layer surrounding the channel layer 350 along the extension direction of the gate structure 600, and the gate electrode layer located on the gate dielectric layer.

The gate dielectric layer is used to isolate the gate electrode layer from the channel layer 350, and the gate electrode layer from the substrate 100.

The material of the gate dielectric layer includes one or more of HfO₂, ZrO₂, HfSiO, HfSiON, HfTaO, HfTiO, HfZrO, Al₂O₃, SiO₂, and La₂O₃. In one embodiment, the gate dielectric layer includes a high-k gate dielectric layer, and the material of the high-k gate dielectric layer includes a high-k dielectric material. Among them, the high-k dielectric material refers to a dielectric material whose relative dielectric constant is greater than the relative dielectric constant of silicon oxide. Specifically, the material of the high-k gate dielectric layer includes HfO₂, ZrO₂, HfSiO, HfSiON, HfTaO, HfTiO, HfZrO, or Al₂O₃.

It should be noted that the gate dielectric layer may also include the gate oxide layer, and the gate oxide layer is located between the high-k gate dielectric layer and the channel layer 350. Specifically, the material of the gate oxide layer may be silicon oxide.

In one embodiment, the gate structure 600 is the metal gate structure, and therefore, the material of the gate electrode layer includes one or more of TiN, TaN, Ta, Ti, TiAl, W, Al, TiSiN, and TiAlC.

Specifically, the gate electrode layer includes the work function layer (not shown) and the electrode layer (not shown) located on the work function layer. The work function layer is used to adjust the threshold voltage of the transistor, and the electrode layer is used to lead out the electrical properties of the metal gate structure.

In other embodiments, the gate electrode layer may also include only the work function layer.

In one embodiment, in the step of forming a gate structure 600 that spans the channel layer structure 212 and fills the second groove 420, the gate structure 600 also spans the isolation stack layer 340 and fills the third groove 430.

The gate structure 600 that spans the isolation stack layer 340 and fills the third groove 430 does not play a working role. The gate structure 600 filled between the vertically adjacent isolation layers 340 makes multiple isolation layers 340 spaced apart vertically to form the isolation stack layer 222.

The embodiments disclosed herein are exemplary only. Other applications, advantages, alternations, modifications, or equivalents to the disclosed embodiments are obvious to those skilled in the art and are intended to be encompassed within the scope of the present disclosure.

What is claimed is:

1. A semiconductor structure, comprising:
a substrate;
a plurality of isolation stack layers located on the substrate, an isolation stack layer of the plurality of isolation stack layers comprising a plurality of isolation layers spaced apart in a vertical direction; and
a plurality of channel layer structures each located on one isolation stack layer, a channel layer structure of the plurality of channel layer structures comprising a plurality of channel layers spaced apart in the vertical direction, sidewalls of adjacent channel layer structures forming a groove penetrating through the plurality of channel layer structures in the vertical direction, and the groove further extending into the plurality of isolation stack layers in the vertical direction.

2. The semiconductor structure according to claim 1, wherein the groove extends in the vertical direction to expose a bottommost isolation layer of the plurality of isolation layers.

3. The semiconductor structure according to claim 1, wherein the groove does not penetrate through the isolation stack layer, and bottommost isolation layers of adjacent isolation stack layers are connected.

4. The semiconductor structure according to claim 1, further comprising:
a gate structure locating over the substrate and across the channel layer structure, wherein the gate structure surrounds each channel layer of the plurality of channel layers and fills between the plurality of adjacent channel layers in the vertical direction.

5. The semiconductor structure according to claim 4, wherein the gate structure is further across the isolation stack layer, surrounds each isolation layer of the plurality of isolation layers, and fills between the plurality of adjacent isolation layers in the vertical direction.

6. The semiconductor structure according to claim 1, wherein the plurality of isolation layers is made of a material including one or more of silicon oxide, silicon nitride, silicon oxynitride, silicon oxycarbide, silicon carbonitride, and silicon carbonitride oxide.

7. A method for forming a semiconductor structure, comprising:
providing a substrate;
forming a channel layer structure over the substrate, wherein the channel layer structure includes a plurality of channel layers spaced apart in a vertical direction, and sidewalls of adjacent channel layer structures form a groove that penetrates the channel layer structure in the vertical direction; and
forming an isolation stack layer between the channel layer structure and the substrate in the vertical direction, wherein the isolation stack layer includes a plurality of isolation layers spaced apart in the vertical direction, and the groove extends into the isolation stack layer over the substrate.

8. The method according to claim 7, wherein forming the channel layer structure comprises:
forming a first material stack over the substrate, wherein the first material stack includes a plurality of alternately stacked channel material layers and first sacrificial layers, wherein the bottommost layer of the first material stack is the channel material layer, and an etching resistance of a first sacrificial layer is less than an etching resistance of the channel material layer; and
patterning the first material stack to form a first groove penetrating the first material stack, wherein the first groove divides the first material stack into a plurality of discrete first stack structures, and retains the channel material layer in the first stack structure as the channel layer, wherein the plurality of channel layers in the first stack structure constitutes the channel layer structure.

9. The method according to claim 8, before forming the first material stack over the substrate, further comprising:
forming a second material stack covering the substrate and under the first material stack, the second material stack comprising a second sacrificial layer and a third sacrificial layer alternately stacked, wherein a plurality of topmost and bottommost layers of the second material stack are the second sacrificial layer, and an etching resistance of the second sacrificial layer is less than that of the third sacrificial layer;
replacing the second sacrificial layer with the isolation layer; and
when patterning the first material stack, patterning the third sacrificial layer and the isolation layer under the channel layer structure to form a second stack structure under the first stack structure, wherein the plurality of isolation layers in the second stack structure constitutes the isolation stack layer, and the groove extends vertically into the isolation stack layer.

10. The method according to claim 9, wherein the third sacrificial layer is made of a same material as the first sacrificial layer.

11. The method according to claim 9, wherein the groove extends vertically to a bottommost isolation layer and exposes the isolation layer.

12. The method according to claim 9, wherein the plurality of bottommost isolation layers in adjacent isolation stack layers are connected, along a surface of the substrate.

13. The method according to claim 9, wherein replacing the second sacrificial layer with the isolation layer comprises:
removing the second sacrificial layer to form a first groove exposing a bottom of the first material stack, a top surface of the substrate, and the third sacrificial layer in the second material stack; and
forming the isolation layer filling the first groove.

14. The method according to claim 9, before forming the isolation layer, further comprising:
forming a dummy gate structure across the first material stack and the second material stack, the dummy gate structure covering part of a top and part of a sidewall of the first material stack, and covering part of the sidewall of the second material layer,
wherein
the first material stack is patterned along the dummy gate structure, and the first material stack on both sides of the dummy gate structure is removed; and
the dummy gate structure is removed to expose the first stack structure and the second stack structure.

15. The method according to claim 14, wherein after removing the dummy gate structure, the method further comprises:
removing the first sacrificial layer in the first stack structure to form a second groove exposing the channel layer; and
forming a gate structure across the channel layer structure and filling the second groove, the gate structure surrounding the channel layer.

16. The method according to claim 15, wherein, when removing the first sacrificial layer in the first stacked structure, the third sacrificial layer in the second stacked structure is removed to form a third groove exposing the isolation layer; and the gate structure is formed across the isolation stack layer and fills the third groove.

17. The method according to claim 8, wherein an epitaxial growth process is used to form the first material stack over the substrate.

18. The method according to claim 8, wherein a material of the first sacrificial layer includes silicon germanium, and a material of the channel material layer includes silicon.

19. The method according to claim 9, wherein an epitaxial growth process is used to form the second material stack covering the substrate.

20. The method according to claim 9 wherein a material of the second sacrificial layer includes silicon germanium, and a material of the third sacrificial layer includes silicon germanium, wherein a molar concentration of a germanium element in the second sacrificial layer is greater than a molar concentration of a germanium element in the third sacrificial layer.
